(19) United States
(12) Patent Application Publication
(10) Pub. No.: US 2003/0095388 A1
(43) Pub. Date: May 22, 2003

(54) Method and apparatus for securing a circuit board to a rigid surface

(76) Inventors: Jinbao Jiao, Gurnee, IL (US); Thomas P. Gall, Northbrook, IL (US); Stanton Rak, Evanston, IL (US); Kevin D. Moore, Hoffman Estates, IL (US)

Correspondence Address: MOTOROLA, INC., 1303 EAST ALGONQUIN ROAD, IL01/3RD, SCHAUMBURG, IL, 60196

(21) Appl. No.: 09/993,208

(22) Filed: Nov. 16, 2001

(51) Int. Cl. H05K 1/00

(52) U.S. Cl. 361/749; 156/307.1; 156/307.5; 174/255

(57) ABSTRACT

A multiple cure adhesive (204) is used to secure a circuit substrate (104) to an underlying rigid surface (106). The adhesive is screen printed on the underlying surface. A first cure is then applied to the adhesive to at least partially cure the adhesive and to make the adhesive tacky. The circuit substrate is mounted on the tacky adhesive and a second cure is applied to the adhesive to firmly secure the circuit substrate to the housing. By screen printing the adhesive on the underlying surface, the process of mounting a circuit substrate on a rigid surface can be completely automated, providing cost saving and waste reduction.

### FIELD OF THE INVENTION

The present invention relates generally to automotive electronic modules, and, in particular, to mechanically securing a circuit board in an automotive electronic module.

### BACKGROUND OF THE INVENTION

Engine mounted electronic control units for automotive engines are subject to a high level of heat that can limit or impair their performance. Typically, in order to reduce the high level of heat and enhance thermal performance, a printed circuit board that includes control circuitry is affixed to a cooling plate. For example, in a direct engine mount application where a Polybent™ printed circuit board, that is a printed circuit board that has a flexible circuit that is bent, is used for packaging an electronic control unit, the printed circuit board is mounted to an aluminum rigidizer. The rigidizer provides mechanical support for the printed circuit board and assists in the dissipation of heat generated by components on the printed circuit board, which heat is conductively transferred from the components to the underlying rigidizer.

Polybent™ printed circuit boards are affixed to a rigidizer by use of a pressure sensitive adhesive (PSA) tape. When manufactured, the adhesive tape, or film, is encased in liners that protect the film during shipment and storage. The adhesive film is then punched by a converter and manually cut into appropriately sized sheets. The sheets are manually loaded into a lamination machine along with the printed circuit boards and rigidizers. A release sheet must be manually peeled off of the film sheets. The film is then applied to the rigidizer and a printed circuit board is applied to the adhesive film, thereby securing the printed circuit board to the rigidizer.

Use of adhesive film poses several problems. It is a manual process when manufacturing operations are becoming increasingly automated. Mistakes made in the manual handling of the film results in film that must be scrapped. Use of an adhesive film in the assembly of electronic control units requires a batch-oven bake cycle to prevent blisters from forming in the film during solder reflow, which baking process is lengthy, as long as 12 hours, and is disruptive of a high volume manufacturing process. In addition, acrylic adhesive films suffer from high temperature instability, typically at temperatures well below maximum operating temperatures of high power field effect transistors (FETs) and the reflow temperatures of lead-free solders, thereby imposing constraints on the manufacturing process and on the operation of electronic control units that employ the adhesive films.

Therefore, a need exists for a method and apparatus for securing a printed circuit board to a rigidizer, which method and apparatus do not require the lengthy baking time or manual investment of the adhesive films and which method and apparatus may be implemented in a high volume manufacturing process.

### BRIEF DESCRIPTION OF THE DRAWINGS

FIG. 1 is an isometric perspective of an electronic control unit in accordance with an embodiment of the present invention.

FIG. 2 is a side view perspective of an electronic control unit in accordance with an embodiment of the present invention.

FIG. 3 is a logic flow diagram of the process of securing a circuit substrate to an underlying surface in accordance with an embodiment of the present invention.

FIG. 4 is a top view of a housing, prior to being bent, with a liquid adhesive screened on the housing in accordance with an embodiment of the present invention.

FIG. 5 is a top view of electronic control unit after a circuit substrate is mounted on a partially cured adhesive, which adhesive has been screened onto an underlying surface, and after solder paste has been screened onto the substrate in accordance with an embodiment of the present invention.

### DETAILED DESCRIPTION OF THE INVENTION

To address the need for a method and apparatus for securing a printed circuit board to a rigidizer, which method and apparatus do not require the lengthy baking time or manual investment of the adhesive films and which method and apparatus may be implemented in a high volume manufacturing process, a multiple cure adhesive is used to secure a circuit substrate to an underlying rigid surface. The adhesive is screen printed on the underlying surface. A first cure is then applied to the adhesive to partially cure the adhesive and to make the adhesive tacky. The circuit substrate is mounted on the partially cured adhesive and a second cure is applied to the adhesive to firmly secure the circuit substrate to the housing. By screen printing the adhesive on the underlying surface, the process of mounting a circuit substrate on a rigid surface can be completely automated, providing cost saving and waste reduction.

Generally, one embodiment of the present invention encompasses a method for securing a printed circuit board to an underlying surface. The method includes steps of applying a liquid adhesive to the underlying surface and applying a first cure to the liquid adhesive after application of the liquid adhesive to produce a liquid adhesive that is at least partially cured. The method further includes steps of placing the printed circuit board on the at least partially cured liquid adhesive and applying a second cure to the liquid adhesive to produce a printed circuit board that is secured to the underlying surface.

Another embodiment of the present invention encompasses an electronic module comprising a rigidizer having a top surface, a printed circuit board disposed on the top surface of the rigidizer, and a liquid adhesive that secures the printed circuit board to the top surface of the rigidizer. The liquid adhesive is cured in at least two stages, and the printed circuit board is placed on the liquid adhesive after a first curing stage of the at least two curing stages and prior to a last curing stage of the at least two curing stages.

The present invention may be more fully described with reference to FIGS. 1-5. FIG. 1 is an isometric perspective of an electronic control unit 100 in accordance with an embodiment of the present invention. Control unit 100 includes an electronic component 102, a circuit substrate 104, and a housing 106. Electronic component 102 is any electronic component or device that can be mounted to a printed circuit board such as, for example, a battery, a capacitor, a resistor, a semiconductor chip, a diode, an inductor, and a coil. Electronic component 102 is mounted onto a surface of circuit substrate 104, as illustrated in FIG. 1. Typically, circuit substrate 104 has a number of electronic components 102 mounted on the surface of the circuit substrate. These electronic components 102 are electrically connected to each other through a number of lands (not shown) and traces (not shown) printed on the surface and on internal layers of circuit substrate 104.

Preferably, circuit substrate 104 is a printed circuit board manufactured from any one of a number of materials known to one of ordinary skill in the art, such as epoxy glass, FR4, and polyimide. In one embodiment of the present invention, circuit substrate 104 is a flat sheet that is formed by conventional methods. Circuit substrate 104 may then be bent in at least one place, as illustrated in FIG. 1. Preferably, circuit substrate 104 is bent using a Polybent™ process, as described in U.S. Pat. No. 5,998,738, the text of which is hereby incorporated by reference herein. The Polybent™ process essentially takes a flat circuit substrate 104 and folds the circuit substrate at least once. If circuit substrate 104 is folded twice, a u-shaped circuit substrate 104 can be formed, as illustrated in FIG. 1. While in the above embodiments circuit substrate 104 is bent using a Polybent™ process, circuit substrate 104 may be bent using any technique known to one of ordinary skill in the art. In another embodiment of the present invention, circuit substrate 104 is not bent, but instead includes two portions that are electrically connected. Circuit substrate 104 may form an L-shape, a T-shape, a U-shape, or any shape desired.

Circuit substrate 104 is secured to a surface of housing 106, which surface comprises an inner surface of the housing when the circuit substrate and housing are bent. Circuit substrate 104 is secured to the surface by a multiple, preferably dual, cure adhesive. Housing 106 surrounds circuit substrate 104 and is designed to shield circuit substrate 104 and electronic components 102 from electrical charge which can damage the circuit substrate and electronic components. Housing 106 also provides mechanical support for circuit substrate 104. Housing 106 is manufactured from materials that are rigid enough to provide a rigid mechanical support for the circuit substrate 104, that is, to function as a rigidizer or stabilizer, and that have elements designed to shield the electronic components from heat, water, chemicals, and electrostatic charge, such as aluminum, steel, engineering grade plastic, magnesium, and zinc or any material that is resistant to chemicals and elements commonly found in an automobile. Preferably housing 106 is further manufactured from thermally conductive materials and is conductively transferred heat by components 102 during operation of electronic control unit 100, thereby assisting the components in dissipating the heat. However, those who are of ordinary skill in the art realize that electronic control unit 100 may be used in low power operations where thermal issues, and the thermal conductivity of housing 106, may be of minor importance.

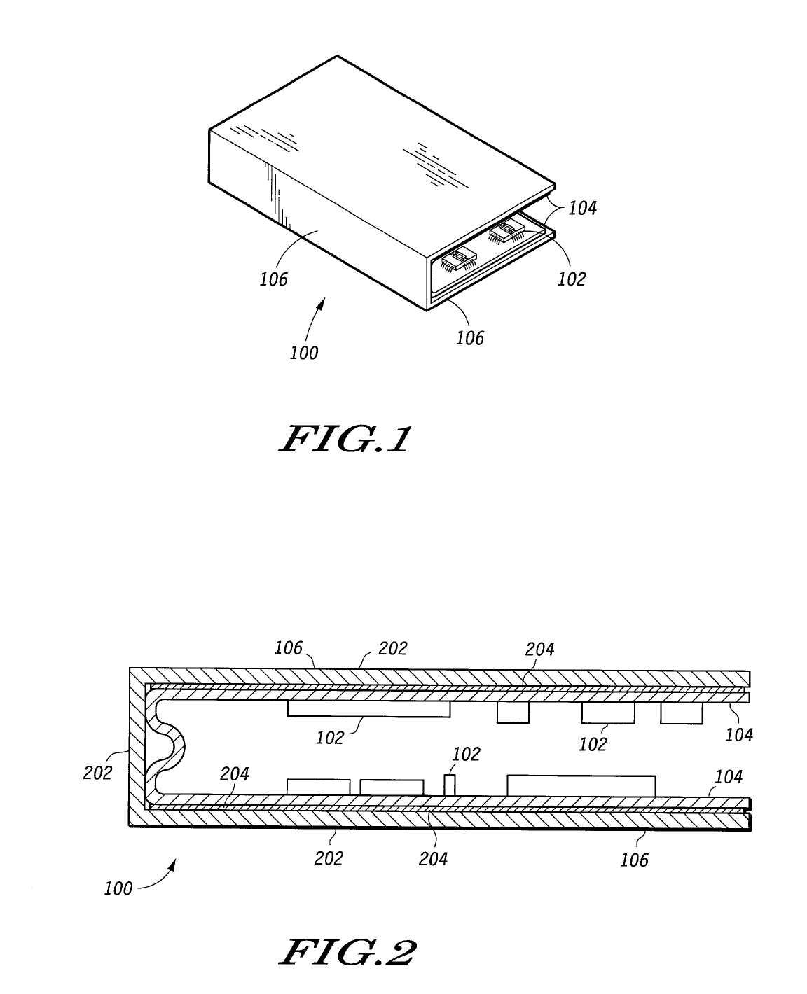

Housing 106 may be a monolithic structure, or housing 106 may be assembled from a series of pieces. FIG. 2 is a side view of electronic control unit 100 in accordance with an embodiment of the present invention. As depicted in FIG. 2, housing 106 is assembled from and includes a series of metal plates 202. Metal plates 202 surround the outside surface of circuit substrate 104 while electronic components 102 are placed in the inside surface of circuit substrate 104. In another embodiment of the present invention, housing 106 includes a single metal plate 202 that surrounds the outside surface of circuit substrate 104, as illustrated in FIG. 1. Preferably, housing 106 is sealed to prevent elements such as dust, water, and other chemicals from entering housing 106 and damaging the electronic components 102.

Referring to FIG. 2, disposed between circuit substrate 104 and housing 106 is an adhesive 204 that serves to secure the circuit substrate to the housing. Adhesive 204 is screen printed on housing 104 and is preferably a liquid adhesive, although any screenable adhesive may be used without departing from the spirit and scope of the present invention. Adhesive 204 is a multiple cure system adhesive, preferably a dual cure system adhesive, such as a B-stage epoxy, that is cured in multiple stages, wherein an earlier curing stage of the multiple stages makes the adhesive tacky to facilitate a mounting of circuit substrate 104 to housing 106 and a later curing stage of the multiple stages firmly secures the substrate to the housing. Preferably, liquid adhesive 204 is a heat cured liquid adhesive, such as dual cure liquid adhesives available from Hernon Manufacturing, Inc., of Sanford, Fla. Alternatively, liquid adhesive 204 may be any type of dual cure liquid adhesive, such the dual cure liquid adhesives available from Hernon Manufacturing, Inc., that are curable by ultraviolet radiation as well as by heat, or photo-sensitive dual cure adhesives available from Hitachi Chemical Company of Japan.

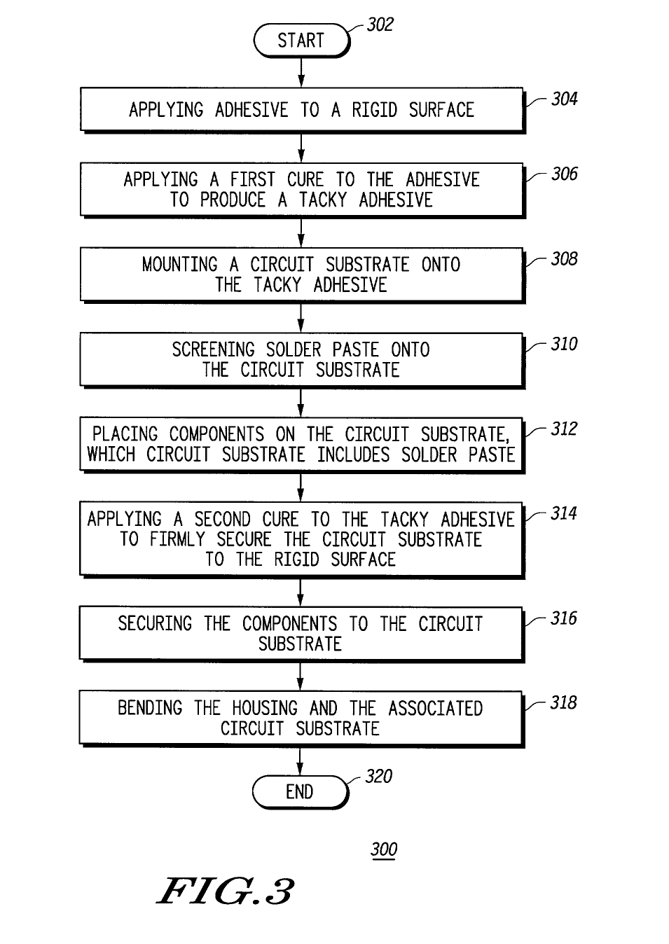

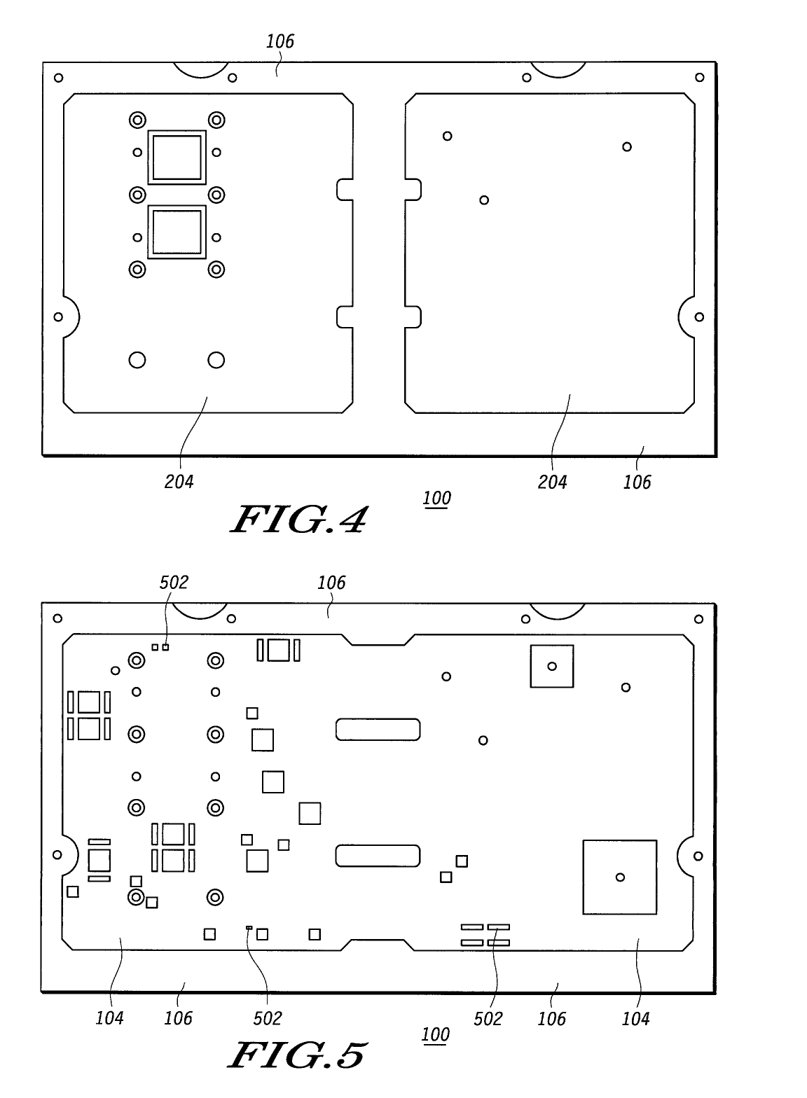

FIG. 3 is a logic flow diagram 300 of the process of securing circuit substrate 104 to an underlying surface, such as a surface of housing 106, in accordance with an embodiment of the present invention. The process starts (302) by applying (304) adhesive 204 to an underlying surface, that is, a surface of housing 106. Preferably, adhesive 204 is applied to the surface of housing 106 by a screen printing process, wherein a screen print is overlaid housing 106 and the adhesive is screened onto area of the housing exposed by the screen print. FIG. 4 is a top view of housing 106, prior to being bent, with liquid adhesive 204 screened on the housing in accordance with an embodiment of the present invention. However, in another embodiment of the present invention, housing 106 may be coated with adhesive 204 and a print, such as a screen print or a photolithographic print, may be subsequently used to expose the adhesive to a curing element, such as ultraviolet radiation, during the curing stages described below.

After being screened on the housing, a first cure is applied (306) to adhesive 204 to at least partially cure the adhesive, that is, to produce a tacky adhesive. Preferably adhesive 204 is a heat cured adhesive and the first cure comprises exposing the adhesive to an elevated temperature. In one embodiment of the present invention, housing 106 and an applied dual stage, heat curable adhesive 204 can be passed through a conveyor oven for approximately 5 minutes at approximately 150° C. to make the adhesive tacky. The thermal treatment of the adhesive also eliminates moisture and volatile materials form the adhesive. In another embodiment of the present invention, wherein adhesive 204 is an air cured or an ultraviolet radiation cured adhesive, the adhesive may be exposed to the curing element, that is, air or ultraviolet radiation, respectively, for a length of time sufficient to make the adhesive tacky. In yet another embodiment of the present invention, wherein housing 106 is coated with adhesive 204, the adhesive may be exposed to a curing element through a print, thereby exposing only selected areas of the adhesive to the curing element.

After the first cure is applied to adhesive 204, and the adhesive is cooled down in the event of a heat cure, circuit substrate 104 is mounted (308) onto the tacky adhesive. Preferably the step of mounting includes steps of placing substrate 104 on adhesive 204 and applying pressure to the substrate, for example by passing a roller over the substrate, to secure the substrate to the adhesive. Preferably, the tacky adhesive 204 is sufficiently cured when the substrate is applied that the application of pressure will not cause the adhesive to spread. Adhesive 204 preferably underlies a sufficient portion of circuit substrate 104 such that the adhesive securely affixes circuit substrate 104 to housing 106 after a second, subsequent cure and provides an acceptable thermal path between the substrate and the housing so as to thermally couple any high heat generating components to the housing.

Solder paste 502 is then screened (310) onto circuit substrate 104 and components 102 are placed (312) on the substrate in accordance with conventional printed circuit board component population techniques. FIG. 5 is a top view of electronic control unit 100 after circuit substrate 104 is mounted on the tacky liquid adhesive 204, which adhesive has been screened onto housing 106, and after solder paste 502 has been screened onto the substrate in accordance with an embodiment of the present invention. Preferably components 102 are surface mountable components that may be auto-placed on circuit substrate 104, thereby providing a maximally automated process of assembling electronic control unit 100. However, those who are of ordinary skill in the art realize that components 102 need not be surface mountable. For example, components 102 may be through-hole parts that may be manually placed on circuit substrate 104.

A second cure is then applied (314) to adhesive 204 to firmly secure circuit substrate 104 to housing 106. However, those who are of ordinary skill in the art realize that the step of applying (314) the second cure may occur any time after circuit substrate 104 has been mounted on adhesive 204. For example, the second cure may be applied to adhesive 204 after circuit substrate 104 has been mounted on adhesive 204 and prior to the screening of solder paste 502 on the circuit substrate. In such event, the second cure may comprise passing housing 106 and the associated tacky adhesive 204 and circuit substrate 104 through a conveyor oven for a second time, again for approximately 5 minutes or whatever length of time is required to firmly secure circuit substrate 104 to housing 106.

The components 102 are secured (316) to circuit substrate 104, housing 106 and the associated circuit substrate are bent (318), and the logic flow ends (320). Preferably the second cure comprises passing housing 106, along with the associated adhesive 204, circuit substrate 104, and components 102, through a reflow oven, thereby applying a second cure to a heat curable adhesive and securing the components 102 to the substrate. Since a heat curable adhesive is very tacky at high temperatures, the first cure has removed moisture and volatile materials from the adhesive and circuit substrate 104 will not blister, wrinkle, or curl in the reflow oven. In another embodiment of the present invention, wherein adhesive 204 is cured by exposure to an element other than heat, such as air or ultraviolet radiation, the second cure comprises again exposing the adhesive 204 to the curing element, such as through vents that may be milled into housing 106, or to the heat of the reflow oven in the event that the adhesive may be cured by exposure to any one or more of multiple curing elements. Components 102 are subsequently secured to circuit substrate 104 by passing the electronic control module 100 through the reflow oven in the event such a step is not included in the second cure.

By using a dual cure liquid adhesive to secure circuit substrate 104 to housing 106, the process of securing the substrate to the housing can be completely automated, reducing the costs and waste inherent in the use of a manually intensive adhesive film. Further cost reduction arises from the screen printing of adhesive instead of punching holes in, and die cutting, the adhesive film. Dual cure system adhesives such as a B-stage epoxy are more thermally stable than acrylic adhesive films and may be exposed to significantly higher temperatures than acrylic adhesive films before degrading in performance, thereby expanding the manufacturing and operating temperature range of electronic control unit 100.

While the present invention has been particularly shown and described with reference to particular embodiments thereof, it will be understood by those skilled in the art that various changes may be made and equivalents substituted for elements thereof without departing from the spirit and scope of the invention. In addition, many modifications may be made to adapt a particular situation or material to the teachings of the invention without departing from the essential scope thereof. Therefore, it is intended that the invention not be limited to the particular embodiments disclosed herein, but that the invention will include all embodiments falling within the scope of the appended claims.

What is claimed is:

1. A method for securing a printed circuit board to an underlying surface comprising steps of:
applying a liquid adhesive to the underlying surface;
applying a first cure to the liquid adhesive after application of the liquid adhesive to produce a liquid adhesive that is at least partially cured;
placing the printed circuit board on the at least partially cured liquid adhesive; and
applying a second cure to the liquid adhesive to produce a printed circuit board that is secured to the underlying surface.

2. The method of claim 1, wherein the step of applying a liquid adhesive to the underlying surface comprises a step of screening the liquid adhesive onto the underlying surface.

3. The method of claim 1, wherein the step of a applying a first cure to the liquid adhesive comprises a step of exposing selected areas of the liquid adhesive to a curing element.

4. The method of claim 1, wherein the liquid adhesive is a dual-cure system adhesive.

5. The method of claim 4, wherein the liquid adhesive is a B-stage epoxy.

6. The method of claim 1, wherein the first cure of the liquid adhesive produces a tacky adhesive that spreads, at most, a negligible amount when the printed circuit board is placed on the at least partially-cured liquid adhesive.

7. The method of claim 1, wherein the printed circuit board is a flexible printed circuit board and wherein the underlying surface is a top surface of a rigidizer to which the flexible printed circuit board is secured.

8. The method of claim 7, further comprising a step of bending the printed circuit board and the rigidizer after the second cure of the liquid adhesive.

9. The method of claim 1, wherein the underlying surface is a surface of a heat sink.

10. The method of claim 1, wherein the liquid adhesive is a heat-curable liquid adhesive, wherein the first cure comprises applying a first heating stage to the liquid adhesive and wherein the second cure comprises applying a second heating stage to the liquid adhesive.

11. The method of claim 1, wherein the liquid adhesive can be cured by exposure to ultraviolet radiation.

12. The method of claim 1, wherein the liquid adhesive can be cured by any one of a plurality of curing methods, wherein the first cure comprises applying a first curing method of the plurality of curing methods to the liquid adhesive and wherein the second cure comprises applying a second, different curing method of the plurality of curing methods to the liquid adhesive.

13. An electronic module comprising:
a rigidizer having a top surface;
a printed circuit board disposed on the top surface of the rigidizer; and
a liquid adhesive that secures the printed circuit board to the top surface of the rigidizer, wherein the liquid adhesive is cured in at least two stages, and wherein the printed circuit board is placed on the liquid adhesive after a first curing stage of the at least two curing stages and prior to a last curing stage of the at least two curing stages.

14. The electronic module of claim 13, wherein the rigidizer is a heat sink.

15. The electronic module of claim 13, wherein the printed circuit board is a flexible printed circuit board and wherein the rigidizer provides mechanical support for the flexible printed circuit board.

16. The method of claim 13, wherein the liquid adhesive is applied to the top surface of the rigidizer by a screening process.

17. The method of claim 13, wherein the first curing stage comprises exposing selected areas of the liquid adhesive to a curing element.

18. The method of claim 13, wherein the liquid adhesive is a dual-cure system adhesive.

19. The method of claim 18, wherein the liquid adhesive is a B-stage epoxy.

20. The method of claim 13, wherein the printed circuit board is a flexible printed circuit board and wherein the printed circuit board and the rigidizer are bent after the second cure of the liquid adhesive.
